(19) United States
(12) Patent Application Publication
(10) Pub. No.: US 2009/0090066 A1
(43) Pub. Date: Apr. 9, 2009

(54) Grinding tool and manufacturing method thereof

(76) Inventor: Chia-Pei Chen, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/905,998

(22) Filed: Oct. 9, 2007

(51) Int. Cl. B24B 1/04; C23C 14/22; B24B 53/12

(52) U.S. Cl. 51/295; 204/192.16; 451/540

(57) ABSTRACT

A manufacturing method for a grinding tool includes: a substrate being provided. A mechanical process is used to form an uneven portion with a regular shape on a surface of the substrate. A coating method is used to uniformly attach a wear resistance layer on a surface of the uneven portion. A forming method is used to uniformly attach a protective layer on a surface of the wear resistance layer. A grinding tool includes a substrate, a wear resistance layer and a protective layer. A surface of the substrate has an uneven portion. The wear resistance layer is uniformly attached on a surface of the uneven portion and corresponds to the shape of the uneven portion. The protective layer is uniformly attached on a surface of the abrasive layer. Thereby, the grinding tool that is corrosion resistance, wear-resistance, heatproof, chemical-resistance and has a regular or irregular shape is formed.

### BACKGROUND OF THE INVENTION

1. Field of the Invention

The present invention relates to a grinding tool and a manufacturing method. In particular, this invention relates to a grinding tool and a manufacturing method that forms an uneven portion on the surface of a substrate. A wear resistance layer and a protective layer are respectively attached on the uneven portion and the surface of the wear resistance layer. The grinding tool has a number of beneficial characteristics, including being corrosion resistance, wear-resistance, durability, heatproof, chemical-resistance and having a regular shape.

2. Description of the Related Art

Grinding tools are extensively applied throughout the manufacturing industry, arts and crafts, household maintenance, and the arts. Grinding tools are not a new technology and are now used for cutting, drilling, and grinding etc.

As the technology has continuously developed, grinding tools have been widely applied to high technology products. For example, in the semiconductor industry, wafers are the core material and are used for manufacturing chips. Because the surface of the wafer needs to be smooth, a chemical mechanical polishing process is used to platanize the wafer.

After the chemical mechanical polishing process, a grinding tool (known as a pad conditioner) is used for dressing the pad. The pad conditioner is normally formed by combining diamonds with the bond material on a disk-shaped or a ring-shaped metal substrate. The grinding tool that is used as a pad conditioner is also called a diamond disk. The pad conditioner is used for dressing the surface of the pad to increase the effectiveness and quality of the polishing and smoothing processes of the wafer. It is also eliminates the small scrap produced in the chemical mechanical polishing process.

The manufacturing method of the pad conditioner of the prior art uses a metal powder solid sintering method to form a metal combining liquid layer on the substrate. Next, a plurality of diamond grits are embedded into the metal combining liquid layer to fasten the diamonds on the substrate. However, the manufacturing method of the prior art utilizes a mechanical or a chemical force to fasten the diamond grits on the substrate is questionable for the bond retention and surface flatness of the conditioner.

Therefore, the diamond grits of the pad conditioner may pop-out or break from the pad conditioner and are located on the pad. When the wafer is polished, the surface of the wafer will be scratched by the pop-out or break diamonds.

Please refer to FIG. 1, which shows a manufacturing method for a pad conditioner 1a. An alloy brazing method is used to form diamond grits 11a on the brazing material layer 12a located on the diamond disk metal substrate 10a. Although this method can increase the pasting force to fasten the diamond grits 11a onto the diamond disk metal substrate 10a, it still doesn't solve the problem of the diamond grits 12a being distributed disproportionately on the pad conditioner metal substrate 10a, and the flatness of conditioner surface. So, the diamond break rate and conditioner dressing performance are all negative impacted. Meanwhile, the diamond grits 11a attached by the alloy brazing method cannot prevent the brazing material layer from being corroded by the acid polishing liquid during the CMP process, and the diamond grits 11a easily depart from the pad conditioner 1a.

Please refer to FIG. 2, which shows a manufacturing method for another pad conditioner 2a. It uses an electroplating method to embed or fasten the diamond grits 21a on the Ni-layer 22a located on the diamond disk metal substrate 20a. However, the diamond grits 21a easily depart from the diamond disk metal substrate 20a during the dressing process and scratch the surface of the wafer. The Ni-layer 22a is corroded by the liquid acid during the CMP process thereby causing the diamond grits 21a to quickly separate from the diamond disk metal substrate 20a and scratch the surface of the wafer.

The pad conditioner of the prior art has the following drawbacks:

1. The diamond grits cannot be firmly fastened onto the pad conditioner metal substrate, and they easily depart from the pad conditioner metal substrate and scratch the surface of the wafer.

2. The distribution of the diamond grits is disproportionate so that the small bits and pieces cannot be eliminated during the grinding process.

3. The combining adhesive attached with the diamond grits is easily corroded by the acid CMP liquid so that the diamond grits fastened onto the substrate will depart from the substrate.

### SUMMARY OF THE INVENTION

One particular aspect of the present invention is to provide a grinding tool and a manufacturing method thereof. An uneven portion is formed on the surface of a substrate, and a wear resistance layer and a protective layer are respectively attached on the uneven portion and the surface of the wear resistance layer. Thereby, the uneven portion with a different shape is formed. The grinding tool has a number of characteristics, including its uneven portion is uniformly distributed and firmly fastened onto the substrate, the grinding tool is corrosion resistance, wear-resistance, highly durable, heatproof, and chemical-resistance. It can be applied to a high speed, high temperature, and high resistant operating environment. The uneven portion will not depart from the substrate due to high temperatures, friction, or liquid acid.

Another particular aspect of the present invention is to provide a grinding tool and a manufacturing method thereof. It uses a mechanical process to form an uneven portion with a regular shape on the substrate. The uneven portion is uniform. Thereby, it solves the problem of wafer scratch caused by the break or pop-out of diamond from the conditioner tool.

A further particular aspect of the present invention is to provide a grinding tool and a manufacturing method thereof. When the user uses the grinding tool in a wafer manufacturing process, the user does not need to test the stability of the grinding tool. Thereby, the amount of testing materials required and the testing costs are reduced.

A manufacturing method for a grinding tool includes:

A substrate is provided. A mechanical process is used to form an uneven portion with a regular shape on a surface of the substrate. A coating method is used to uniformly attach a wear resistance layer on a surface of the uneven portion. The wear resistance layer corresponds to the shape of the uneven portion. A forming method is used to uniformly attach a protective layer on a surface of the wear resistance layer. The protective layer corresponds to the shape of the uneven portion.

A grinding tool includes a substrate, a wear resistance layer and a protective layer. A surface of the substrate has an uneven portion. The wear resistance layer is uniformly attached on a surface of the uneven portion and corresponds to the shape of the uneven portion. The protective layer is uniformly attached on a surface of the wear resistance layer and corresponds to the shape of the uneven portion.

Thereby, the wear resistance layer and the protective layer are firmly attached on the surface of the substrate. The wear resistance layer is highly durable and will not depart from the substrate due to abrasion, high temperatures, or corrosion caused by the liquid acid. The problems of the wafer being scratched and damaged are solved. When the grinding tool is used to dress the pad, the user does not need to test whether the wear resistance layer is still fastened onto the substrate or not. The testing materials and testing costs are reduced.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a schematic diagram of the pad conditioner manufactured by a prior art;

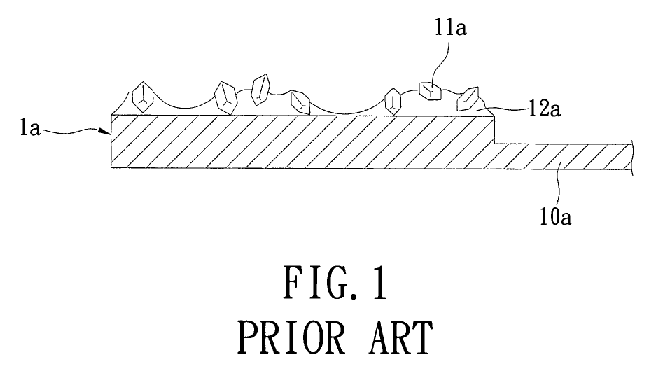

FIG. 2 is a schematic diagram of the pad conditioner manufactured by another prior art;

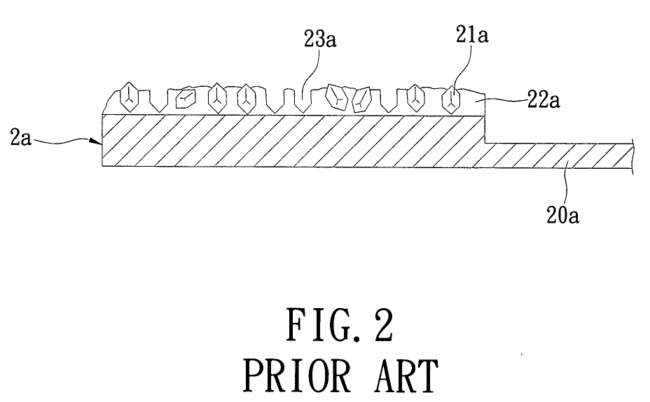

FIG. 3 is a flow chart of the manufacturing method for a grinding tool of the present invention;

FIG. 4 is a schematic diagram of the grinding tool of the present invention;

FIG. 4A is a detailed view of FIG. 4.

FIG. 5 is a schematic diagram of the grinding tool of the second embodiment of the present invention;

FIG. 6 is a perspective view of the grinding tool of the present invention;

FIG. 7 is another perspective view of the grinding tool of the present invention;

FIG. 8 is a perspective view of the grinding tool of the second embodiment of the present invention; and

FIG. 9 is another perspective view of the grinding tool of the second embodiment of the present invention.

### DETAILED DESCRIPTION OF THE PREFERRED EMBODIMENTS

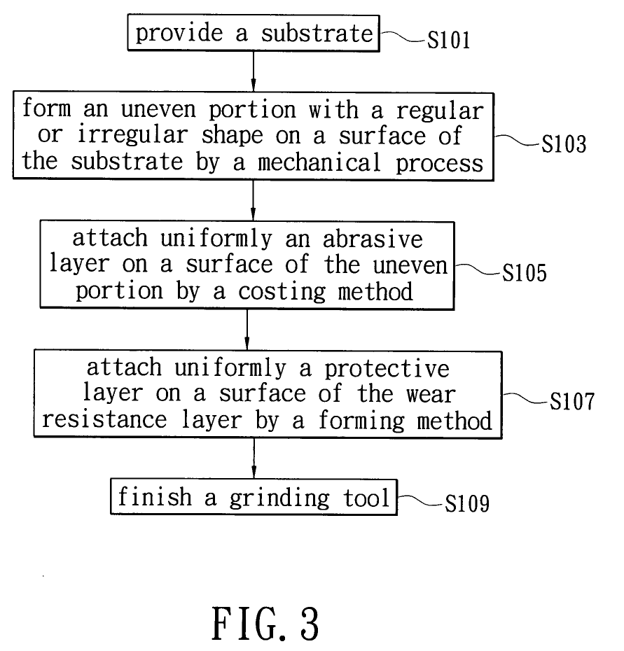

Please refer to FIGS. 3˜9, which show a flow chart of the manufacturing method for a grinding tool of the present invention and the related schematic diagrams.

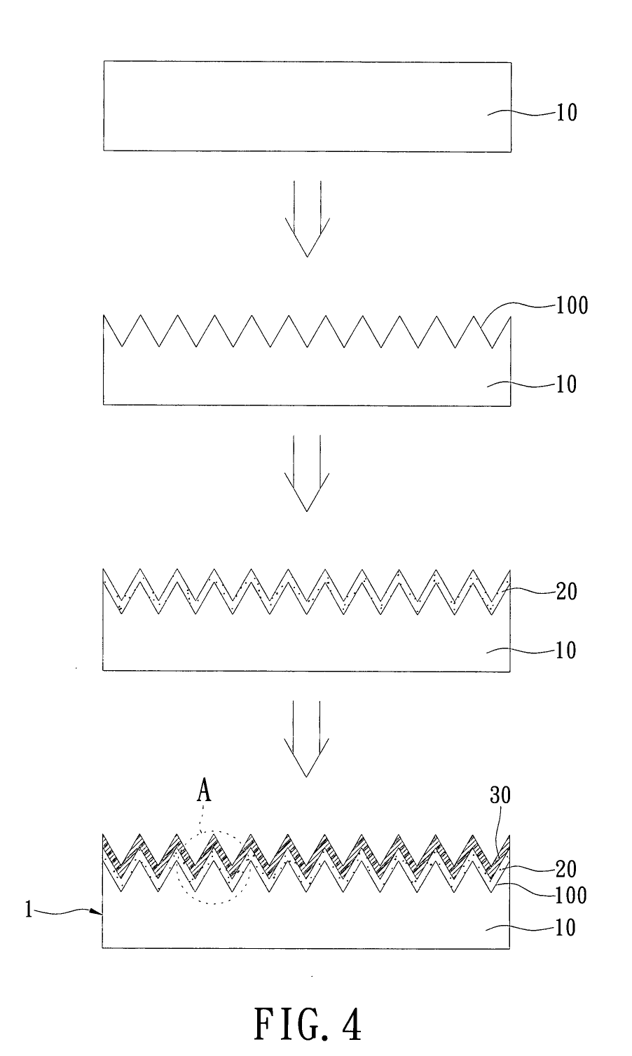

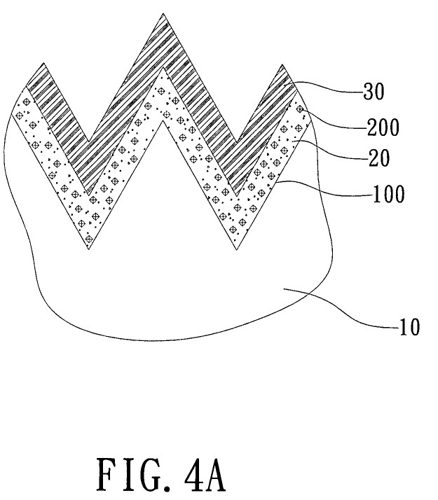

Please refer to FIGS. 3 and 4. The manufacturing method for a grinding tool 1 includes a substrate 10 being provided (S101). Next, a mechanical process is used to form an uneven portion 100 with a regular shape on a surface of the substrate 10 (S103). A costing method is used to uniformly attach a wear resistance layer 20 on a surface of the uneven portion 100 (S105). Finally, a forming method is used to uniformly attach a protective layer 30 on a surface of the wear resistance layer 20 (S107). Thereby, a grinding tool is manufactured (S109).

Both the wear resistance layer 20 and the protective layer 30 correspond to the shape of the uneven portion 100. The uneven portion 100 is formed by one of the following mechanical processes, including a wire EDM cutting process, a laser machining process, a dicing saw process, a metal injection mold method, a ceramic injection mold method, a die-casting process, a punching method, or a powder metallurgy process. The uneven portion 100 can be formed with different shapes or dimensions.

Please refer to FIG. 4a. The wear resistance layer 20 can be formed by one of the following methods.

Method one: in a vacuum system, an amorphous or crystalline phase of diamond layer (as shown in FIG. 4a) are uniformly attached on the surface of the uneven portion 100 by chemical vapor deposition (CVD), physical vapor deposition (PVD), or sputtering.

Method two: micro or nano diamond grits 200 are uniformly attached on the surface of the uneven portion 100 by an electroplating method or an electroless plating method. Thereby, the wear resistance layer 20 is firmly attached on the uneven portion 100.

Method three: micro or nano diamond grits 200 are mixed with Ni, Co, Cu, or Cr by a chemical electroplating method, and then formed on the uneven portion 100 by a composite electroplating or chemical plating method.

The protective layer 30 is made of a PEEK material. PEEK is a composite material and is highly durable, has a good lubricity, is chemical-resistant, has a high loading and has a good adhesive force. The protective layer 30 is formed on the surface of the abrasive layer 20 by a forming method, including a painting method, a spraying method, a pasting method, or a printing method.

In this embodiment, the PEEK is composed of PTFE or a semi-crystal hot-plastic. When the grinding tool 1 is operating in the grinding process, the protective layer 30 provides a highly durable surface for the grinding tool 1. The protective layer 30 is not easily corroded by the liquid acid so that the wear resistance layer 20 is not corroded. The protective layer 30 protects the wear resistance layer 20 when the grinding tool 1 is operating at high temperatures, high pressure, or in a high friction environment.

Please refer to FIGS. 4˜9. The uneven portion 100 has a regular sawtooth shape. The sawtooth shape can be a pyramid shape or a trapezoid shape. However, in this present invent, the shape of the uneven portion 100 is not limited to above. The material of the substrate 10 can be stainless steel, ceramic, plastic, superalloy and any anti-corrosion alloy. The ceramic can be an oxide ceramic, a carbide ceramic, or a nitride ceramic. Thereby, the substrate 10 cannot be corroded by the liquid acid. The substrate 10 can be circular-disk shaped, or any other circular geometrical shape.

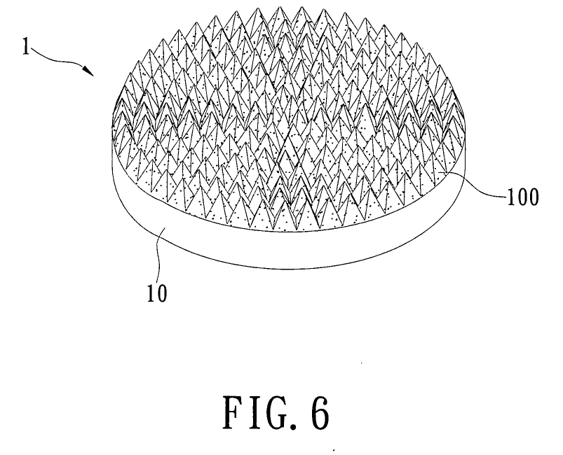

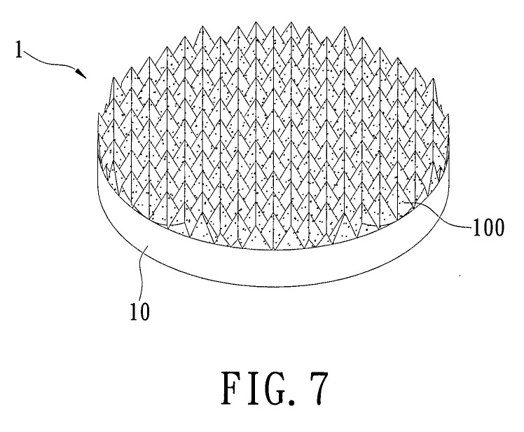

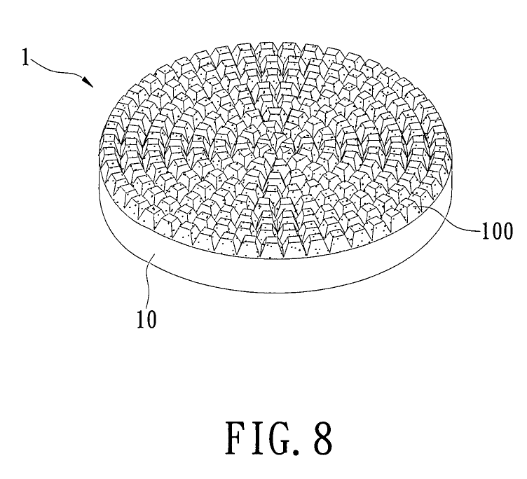

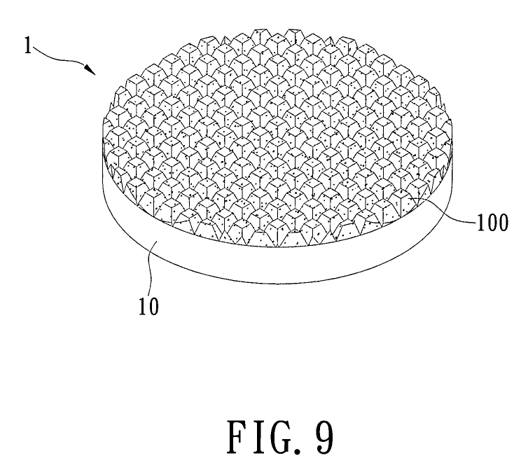

The uneven portion 100 can be formed on the substrate 10 by the described mechanical processes and is disposed on the substrate 10 using a different method. As shown in FIGS. 6 and 7, the shape of the uneven portion 100 can be a pyramid and is disposed on the substrate 10 in concentric circles or by using a rectangular disposing method. The height and shape of the uneven portion 100 can be the same or different. As shown in FIGS. 8 and 9, the shape of the uneven portion 100 can be a trapezoid and is disposed on the substrate 10 in concentric circles or by using a rectangular disposing method. The height and shape of the uneven portion 100 can be the same or different.

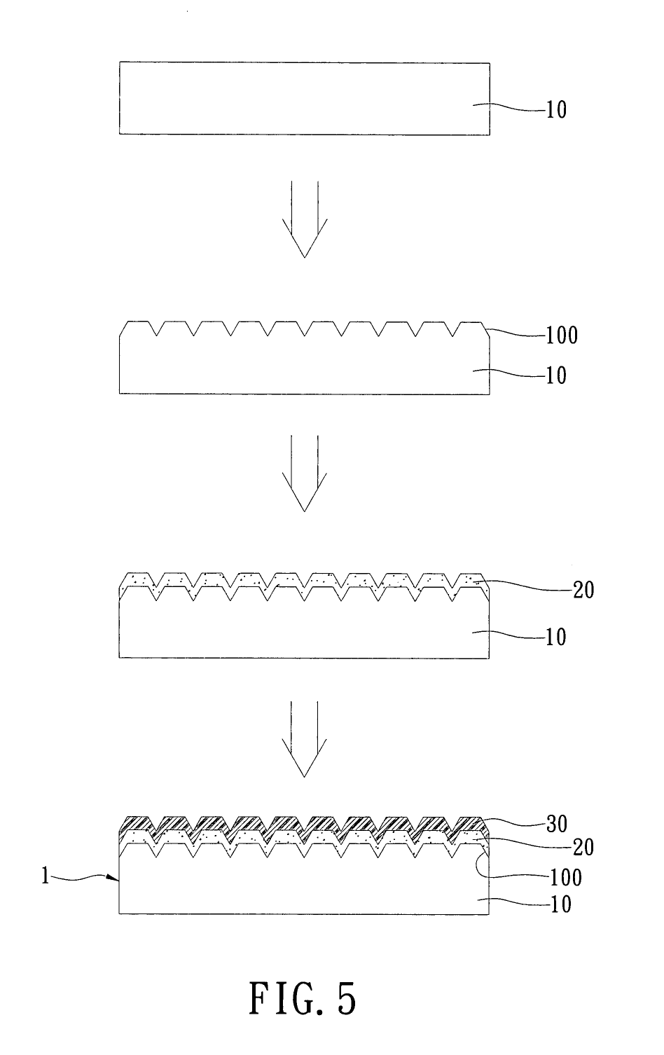

Please refer to FIGS. 4 and 5. A grinding tool 1 includes a substrate 10, a wear resistance layer 20 attached on a surface of the substrate 10, and a protective layer 30 attached on a surface of the wear resistance layer 20. The surface of the substrate 10 has an uneven portion 100. The wear resistance layer 20 and the protective layer 30 are uniformly attached on a surface of the uneven portion 100 and correspond to the shape of the uneven portion 100. The material of the substrate 10 can be stainless steel, ceramic, plastic, superalloy and any anti-corrosion alloy. The substrate 10 can be circular-disk shaped, or any other circular geometrical shape. The shape of the craggy portion 100 can be a sawtooth shape or other uneven shapes that can be used for a grinding process. In this embodiment, the sawtooth shape can be a pyramid shape or a trapezoid shape.

The uneven portion 100 is formed by one of following the mechanical process, including a wire EDM cutting process, a laser machining process, a dicing saw process, a metal injection mold method, a ceramic injection mold method, a die-casting process, a punching method, or a powder metallurgy process.

The wear resistance layer 20 is a diamond layer formed by chemical vapor deposition (CVD), physical vapor deposition (PVD), or sputtering in a vacuum system. The diamond layer can be amorphous or crystalline phase. Alternatively, the wear resistance layer 20 can be a diamond layer formed by an electroplating method or an electroless plating method. The diamond layer is composed of micro or nano diamond grid 200. Furthermore, the wear resistance layer 20 can be a diamond layer formed by a chemical electroplating method. The diamond layer is composed of micro or nano diamond grid 200 and mixed with Ni, Co, Cu, or Cr. This means the wear resistance layer 20 is formed by a composite electroplating or chemical plating method.

The protective layer 30 is made of a PEEK material. PEEK is a composite material and is highly durable, has a good lubricity, is chemical-resistant, has a high loading and has a good adhesive force. The protective layer 30 can be formed on the surface of the abrasive layer 20 by one of the following forming methods, including a painting method, a spraying method, a pasting method, or a printing method. PEEK is composed of PTFE or a semi-crystal hot-plastic.

The protective layer 30 provides a highly durable surface for the grinding tool 1. The protective layer 30 is not easily corroded by liquid acid so that the abrasive layer 20 is not corroded. The protective layer 30 also can absorb heat, pressure and friction when it is used in a grinding process.

The grinding tool 1 can be a pad conditioner used in the chemical mechanical process (CMP). The pad conditioner is a diamond disk.

The present invention has the following characteristics:

1. The uneven portion with a variety of shapes can be formed on the surface of the substrate by a pre-determined mechanical process. The requirements for different grinding operations are achieved.

2. The diamond grits is not corroded by acid or alkali liquid. The diamond grits will not depart from the substrate to scratch or damage the wafer.

3. By utilizing the characteristic of PEEK of the protective layer, the grinding tool has the following characteristics, including corrosion resistance, wear-resistance, durability, heatproof, and chemical-resistance in the wafer polishing process. The usage life is increased.

4. By using the wear resistance layer and the protective layer, the user does not need to test the stability of the grinding tool when the grinding tool is used for a grinding process. The testing process for the grinding tool is omitted. The testing material and testing cost are reduced.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A manufacturing method for a grinding tool, comprising:
(a) providing a substrate;
(b) forming an uneven portion with a regular or irregular shape on a surface of the substrate by a mechanical process;
(c) attaching uniformly an wear resistance layer on a surface of the uneven portion by a coating method, wherein the wear resistance layer corresponds to the shape of the uneven portion; and
(d) attaching uniformly a protective layer on a surface of the wear resistance layer by a forming method, wherein the protective layer corresponds to the shape of the uneven portion.

2. The manufacturing method for a grinding tool as claimed in claim 1, wherein the uneven portion is formed by one of the following mechanical processes, including a wire EDM cutting process, a laser machining process, a dicing saw process, a metal injection mold method, a ceramic injection mold method, a die-casting process, a punching method, or a powder metallurgy process, in the step (b).

3. The manufacturing method for a grinding tool as claimed in claim 1, wherein the wear resistance layer is formed in a vacuum system that forms an amorphous or crystalline phase of diamond layer on the uneven portion by chemical vapor deposition (CVD), physical vapor deposition (PVD), or sputtering, in the step (c).

4. The manufacturing method for a grinding tool as claimed in claim 1, wherein the wear resistance layer is implemented by forming micro or nano diamond grits on the uneven portion by an electroplating method or an electroless plating method, in the step (c).

5. The manufacturing method for a grinding tool as claimed in claim 1, wherein the wear resistance layer is implemented by mixing micro or nano diamond grains on the uneven portion with Ni, Co, Cu, or Cr and formed on the uneven portion by a composite electroplating or chemical plating method, in the step (c).

6. The manufacturing method for a grinding tool as claimed in claim 1, wherein a shape of the uneven portion is sawtooth, and the sawtooth shape is a pyramid shape or a trapezoid shape.

7. The manufacturing method for a grinding tool as claimed in claim 1, wherein the substrate has a circular disk shape, the uneven portions are formed on the substrate via a regular disposing method, and the uneven portions have the same height and shape.

8. The manufacturing method for a grinding tool as claimed in claim 1, wherein the protective layer is a PEEK material, the protective layer is uniformly attached on the surface of the abrasive layer by one of the following forming methods, including a painting method, a spraying method, a pasting method, or a printing method, and the PEEK material is composed of PTFE or a semi-crystal hot-plastic.

9. The manufacturing method for a grinding tool as claimed in claim 1, wherein the substrate is made of stainless steel, ceramic, plastic, superalloy and any anti-corrosion alloy.

10. The manufacturing method for a grinding tool as claimed in claim 9, wherein the ceramic is an oxide ceramic, a carbide ceramic, or a nitride ceramic

11. The manufacturing method for a grinding tool as claimed in claim 1, wherein the grinding tool is a pad conditioner used in the CMP process for dressing the pad, and the pad conditioner is a diamond disk.

12. A grinding tool, comprising:
a substrate, wherein a surface of the substrate has an uneven portion;
a wear resistance layer uniformly attached on a surface of the uneven portion and corresponding to the shape of the uneven portion; and
a protective layer uniformly attached on a surface of the wear resistance layer and corresponding to the shape of the uneven portion.

13. The grinding tool as claimed in claim 12, wherein the uneven portion is formed by one of the mechanical processes, including a wire EDM cutting process, a laser machining process, a dicing saw process, a metal injection mold method, a ceramic injection mold method, a die-casting process, a punching method, or a powder metallurgy process.

14. The grinding tool as claimed in claim 12, wherein the wear resistance layer is formed by chemical vapor deposition, physical vapor deposition or sputtering in a vacuum system and a wear resistance layer is made of an amorphous or crystalline phase of diamond layer.

15. The grinding tool as claimed in claim 12, wherein the wear resistance layer is formed by an electroplating method or an electroless plating method, and an wear resistance layer is made of micro or nano diamond grits

16. The grinding tool as claimed in claim 12, wherein the wear resistance layer is implemented by mixing diamond grits with Ni, Co, Cu, or Cr by a chemical plating process, and the diamond grits is micro or nano diamond grits.

17. The grinding tool as claimed in claim 12, wherein a shape of the uneven portion has a sawtooth shape, and the sawtooth shape is a pyramid shape or a trapezoid shape.

18. The grinding tool as claimed in claim 12, wherein the substrate has a circular disk shape, the uneven portions are formed on the substrate in a regular disposing method, and the uneven portion has the same height and shape.

19. The grinding tool as claimed in claim 12, wherein the protective layer is a PEEK material, the protective layer is uniformly attached on the surface of the abrasive layer by one of the following forming methods, including a painting method, a spraying method, a pasting method, or a printing method, and PEEK is composed of PTFE or a semi-crystal hot-plastic.

20. The grinding tool as claimed in claim 12, wherein the substrate is made of stainless steel, ceramic, plastic, superalloy and any anti-corrosion alloy.

21. The grinding tool as claimed in claim 20, wherein the ceramic is an oxide ceramic, a carbide ceramic, or a nitride ceramic

22. The grinding tool as claimed in claim 12, wherein the grinding tool is a pad conditioner used in the CMP process for dressing the pad, and the pad conditioner is a diamond disk.
